(19) United States
(12) Patent Application Publication
(10) Pub. No.: US 2007/0161252 A1
(43) Pub. Date: Jul. 12, 2007

(54) Method of manufacturing flash memory and flash memory manufactured from the method

(75) Inventors: Jin Ho Kim, Seoul (KR); Hyo Sang An, Seoul (KR)

Correspondence Address: MAYER, BROWN, ROWE & MAW LLP, 1909 K STREET, N.W., WASHINGTON, DC, 20006, US

(73) Assignee: Dongbu Electronics Co., Ltd.

(21) Appl. No.: 11/645,504

(22) Filed: Dec. 27, 2006

(30) Foreign Application Priority Data
Dec. 29, 2005 (KR) 10-2005-0134447

(51) Int. Cl. H01L 21/336; H01L 21/461; H01L 21/302

(52) U.S. Cl. 438/734; 438/257; 438/706

(57) ABSTRACT

Method of manufacturing flash memories comprise forming a floating gate, a control gate, and a dielectric layer in the same etching apparatus. In some embodiments, Cl₂, Ar, HBr, HeO₂, He, CF₄, and CHF₃ gases are used for etching and forming layers. The flash memories manufactured from the method are disclosed.

### CROSS-REFERENCE TO RELATED APPLICATIONS

The present invention claims priority of Korean patent application number 10-2005-0134447, filed on Dec. 29, 2005, being incorporated by reference in its entirety.

### TECHNICAL FIELD

The present invention relates to a flash memory, and to method of manufacturing a flash memory.

### BACKGROUND

Semiconductor memory devices are divided into random access memory (RAM) and read only memory (ROM). RAM is volatile meaning data is lost with the lapse of time, but data can be rapidly input and output. Some examples of RAM are dynamic random access memory (DRAM), and static random access memory (SRAM). ROM can maintain the state of data once the data is input, but data generally cannot input and output as rapidly as for RAM. Some examples of ROM are a programmable ROM (PROM), an erasable PROM (EPROM), and electrically EPROM (EEPROM). Customer demand for EEPROM which can electrically program and erase data, has increased. The EEPROM cell or a flash memory cell having an erase function has a stacked gate structure in which a floating gate, a dielectric layer, and a control gate are stacked.

The dielectric layer is formed between the floating gate and the control gate. Since the floating gate (or the control gate) and the dielectric layer have different etching ratios, processes of forming the floating gate and the control gate must be separately performed.

Therefore, the floating gate and the control gate are etched by different etching apparatuses.

As a result, when the flash memory is manufactured by the conventional method, it takes a long time and the reliability of the device deteriorates due to differences between the etching apparatuses used.

### SUMMARY

Therefore, there is a need to provide a method of manufacturing a flash memory in which a floating gate, a control gate, and a dielectric layer can be formed in the same etching apparatus and there is a need for flash memory manufactured from this method.

In accordance with a preferred embodiment of the present invention, there is provided a method of manufacturing a flash. The method includes the steps of sequentially forming a gate oxide layer, a first polysilicon layer, an interlayer insulating layer, and a second polysilicon layer on the entire surface of a semiconductor substrate, forming a photoresist pattern on the second polysilicon layer, removing the exposed portion of the second polysilicon layer using the photoresist pattern as a mask using Cl₂, HBr, HeO₂, and CF₄ gases to form a control gate, removing the exposed portion of the interlayer insulating layer using the photoresist pattern as mask using Ar and CHF₃ gases to form a dielectric layer, and the exposed portion of the first polysilicon layer using the photoresist pattern as a mask using the HBr and HeO₂ gases to form a floating gate.

In some embodiments, the method further comprises removing of the photoresist pattern and removing the gate oxide layer using the control gate as a mask to form a tunnel oxide layer.

### BRIEF DESCRIPTION OF THE DRAWINGS

The above and other objects and features of the present invention will become apparent from the following description of some embodiments given in conjunction with the accompanying drawings, in which:

FIGS. 1A to 1F are sectional views illustrating processes of a method of manufacturing a flash memory according to some embodiments of the present invention.

### DETAILED DESCRIPTION

Hereinafter, a method of manufacturing a flash memory and the memory manufactured from the method according to some embodiments will be described in detail with reference to the attached drawings

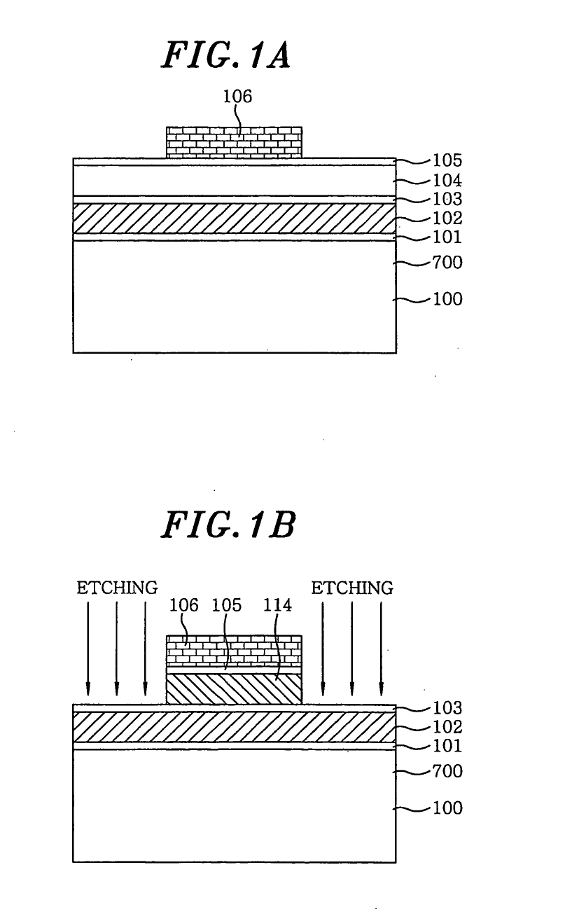

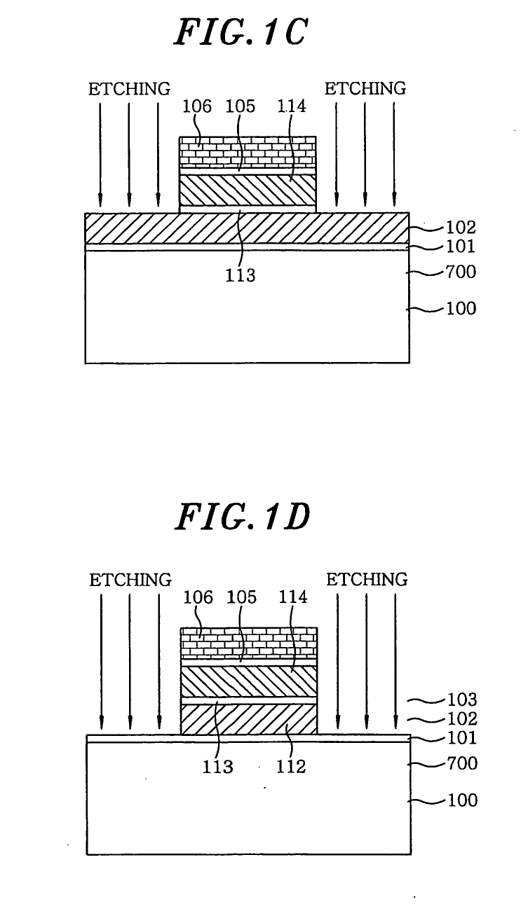

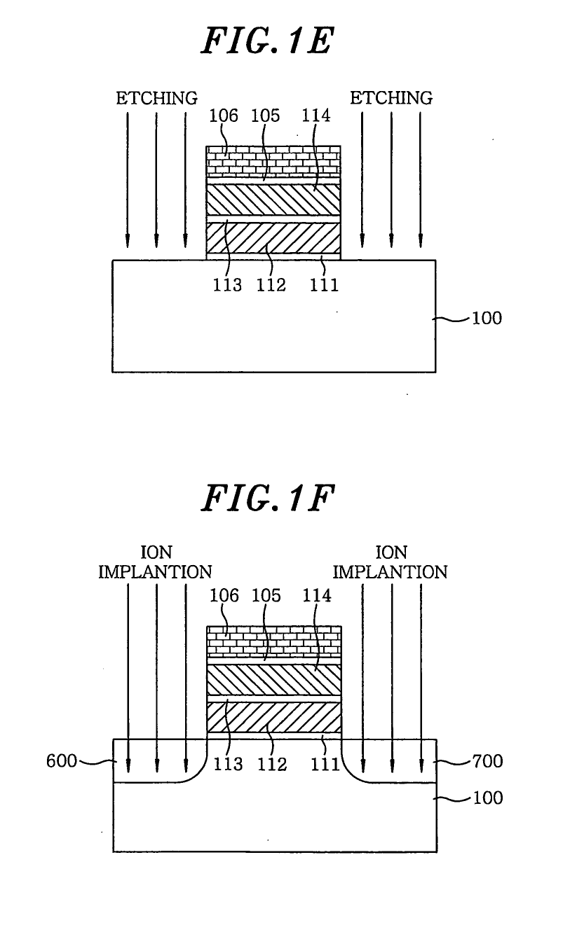

FIGS. 1A to 1F are sectional views illustrating a method of manufacturing a flash memory according to some embodiments of the disclosure.

First, as illustrated in FIG. 1A, a substrate 100 is provided and an oxide layer (or an oxide nitride layer) to be used as a tunnel oxide layer is grown on the entire surface of the substrate 100 to a thickness of about 96 Å to form a gate oxide layer 101 of a unit cell. Then, a first electrode layer to be used as a floating gate, for example, a first polysilicon layer 102 is deposited on the gate oxide layer 101 to a thickness of 1,000 Å.

Then, POCl₃ that contains a large amount of P is deposited to dope the first polysilicon layer 102 to be n+ type.

Then, the first polysilicon layer 102 is oxidized to grow a first oxide layer of about 60 Å, then a nitride layer of about 80 Å is deposited on the first oxide layer, then the nitride layer is oxidized to grow a second oxide layer of about 60 Å these three layers form an interlayer insulating layer 103 comprising oxide/nitride/oxide (ONO).

Then, a second electrode layer to be used as a control gate, for example, a second polysilicon layer 104 of 2,100 521 doped to be n+ type is formed on the interlayer insulating layer 103.

Then, an anti-reflection coating layer 105 of 600 Å is formed on the second polysilicon layer 104. The antireflection coating layer (ARC) 105 may not be formed.

Then, the ARC 105 is coated with photoresist and the photoresist is patterned through exposure and development to form a photoresist pattern 106 of 0.6 μm.

The substrate 100 on which the above layers are formed is loaded in a plasma etching apparatus.

Then, as illustrated in FIG. 1B, the exposed ARC 105 and the second polysilicon layer 104 are removed through a first plasma etching process using the photoresist pattern 106 as a mask. Therefore, a control gate 114 is formed in the part covered with the photoresist pattern 106.

Here, the gases supplied to the plasma etching apparatus during the first plasma etching process are as follows.

The first plasma etching process is divided into three steps.

That is, in the first etching step, a natural oxide layer formed on the second polysilicon layer 104 is removed. The gases used in the step are Ar gas and CF₄ gas.

In the first step, pressure in the plasma etching apparatus is maintained at about 2 to 8 mT and the Ar gas is supplied to the plasma etching apparatus under the above-described pressure by about 80 to 200 sccm for five seconds. At the same time, the CF₄ gas is supplied to the plasma etching apparatus by about 75 to 195 sccm.

At this time, the power of the source voltage supplied to the plasma etching apparatus is about 300 to 700W, the power of a bias voltage is about 50 to 150 W, and a direct current voltage is about 19.5 V. The temperature at the center of the rear surface of the substrate 100 is maintained at about 4 T and the temperature at the edge of the rear surface of the substrate 100 is maintained as about 16 T. The temperature of the substrate 100 can be controlled by supplying He gas to the rear surface of the substrate 100.

Through the first step of the first plasma etching process, the natural oxide layer formed on the surface of the second polysilicon layer 104 is removed.

Then, in the second step of the first plasma etching process, Cl₂, HBr, HeO₂, and CF₄ gases are used to remove the second polysilicon layer 104.

In the second step, pressure in the plasma etching apparatus is maintained as about 2 to 10 mT and the Cl2 gas is supplied to the plasma etching apparatus under the above-described pressure by about 15 to 95 sccm for 55 seconds. At the same time, the HBr gas is supplied to the plasma etching apparatus by about 80 to 250 sccm, the HeO₂ gas is supplied to the plasma etching apparatus by about 8 to 64 sccm, and the CF₄ gas is supplied to the plasma etching apparatus by about 12 to 64 sccm.

At this time, the power of the source voltage supplied to the plasma etching apparatus is about 450 to 790 W, the power of the bias voltage is about 35 to 95 W, and the direct current voltage is about 11.5 V. The temperature at the center of the rear surface of the substrate 100 is maintained at about 4 T and the temperature at the edge of the rear surface of the substrate 100 is maintained as about 16 T.

Through the second step of the first plasma etching process, the exposed second polysilicon layer 104 is almost removed.

Then, in the third step of the first plasma etching process, the HBr, HeO₂, and He gases are used to completely remove the exposed second polysilicon layer 104.

In the second step, pressure in the plasma etching apparatus is maintained as about 25 to 125 mT and the HBr gas is supplied to the plasma etching apparatus under the above-described pressure by about 120 to 650 sccm for 120 seconds. At the same time, the HeO₂ gas is supplied to the plasma etching apparatus by about 8 to 36 sccm and the He gas is supplied to the plasma etching apparatus by about 125 to 225 sccm.

At this time, the power of the source voltage supplied to the plasma etching apparatus is about 210 to 680 W, the power of the bias voltage is about 28 to 135 W, and the direct current voltage is about 19.5 V. The temperature at the center of the rear surface of the substrate 100 is maintained at about 4 T and the temperature at the edge of the rear surface of the substrate 100 is maintained as about 16 T.

Through the third step of the first plasma etching process, the exposed second polysilicon layer 104 is completely removed.

The second polysilicon layer 104 exposed using the photoresist pattern 106 as a mask is removed so that a control gate 114 is formed in the part covered with the photoresist pattern 106. Here, the exposed ARC 105 is also removed using the photoresist pattern 106 as a mask.

Then, as illustrated in FIG. 1C, the interlayer insulating layer 103 exposed using the photoresist pattern 106 as a mask is removed through a second plasma etching process. Therefore, a dielectric layer 113 is formed in the part covered with the photoresist pattern 106.

The gases supplied to the plasma etching apparatus during the second plasma etching process are as follows.

In the second plasma etching process, a part of the interlayer insulating layer 103 is removed. In this step, Ar and CHF₃ gases are used.

In the second plasma etching process, pressure in the plasma etching apparatus is maintained at about 0.9 to 8 mT, and the Ar gas is supplied to the plasma etching apparatus under the above-described pressure by about 45 to 165 sccm for 50 seconds. At the same time, the CHF₃ gas is supplied to the plasma etching apparatus by about 50 to 350 sccm.

At this time, the power of the source voltage supplied to the plasma etching apparatus is about 120 to 595 W, the power of the bias voltage is about 20 to 250 W, and the direct current voltage is about 11.5 V. The temperature at the center of the rear surface of the substrate 100 is maintained at about 4 T and the temperature at the edge of the rear surface of the substrate 100 is maintained as about 16 T.

Through the second plasma etching process, the exposed interlayer insulating layer 103 is removed.

Then, as illustrated in FIG. 1D, the first polysilicon layer 102 exposed using the photoresist pattern 106 as a mask is removed through a third plasma etching process. Therefore, a floating gate 112 is formed in the part covered with the photoresist pattern 106.

The gases supplied to the plasma etching apparatus during the third plasma etching process are as follows.

The third plasma etching process is divided into three steps.

In the first etching step, a part of the exposed second polysilicon layer 104 is removed. In this step, the Cl₂, HBr, HeO₂, and CF₄ gases are used.

In the first step, pressure in the plasma etching apparatus is maintained at about 3.8 to 9.0 mT and the Cl₂ gas is supplied to the plasma etching apparatus under the above-described pressure by about 20 to 90 sccm for 11 seconds. At the same time, the HBr gas is supplied to the plasma etching apparatus by about 12 to 95 sccm, the HeO₂ gas is supplied to the plasma etching apparatus by about 12 to 35 sccm, and the CF₄ gas is supplied to the plasma etching apparatus by about 80 to 300 sccm.

At this time, the power of the source voltage supplied to the plasma etching apparatus is about 400 to 800 W, the power of a bias voltage is about 12 to 95 W, and a direct current voltage is about 8 V. The temperature at the center of the rear surface of the substrate 100 is maintained at about 4 T and the temperature at the edge of the rear surface of the substrate 100 is maintained as about 16 T.

Through the first step of the third plasma etching process, a part of the exposed first polysilicon layer 102 is removed.

Then, in the second step of the third plasma etching process, the HBr and HeO₂ gases are used to remove most of the exposed first polysilicon layer 102.

In the second step, pressure in the plasma etching apparatus is maintained as about 8 to 21 mT and the HBr gas is supplied to the plasma etching apparatus under the above-described pressure by about 100 to 250 sccm for 38 seconds. At the same time, the HeO₂ gas is supplied to the plasma etching apparatus by about 12 sccm.

At this time, the power of the source voltage supplied to the plasma etching apparatus is about 125 to 520 W, the power of the bias voltage is about 10 to 95 W, and the direct current voltage is preferably about 11.5 V. The temperature at the center of the rear surface of the substrate 100 is maintained at about 4 T and the temperature at the edge of the rear surface of the substrate 100 is maintained as about 16 T.

Through the second step of the third plasma etching process, most of the exposed first polysilicon layer 102 is removed.

Then, in the third step of the third plasma etching process, the HBr, HeO₂, and He gases are used to completely remove the exposed first polysilicon layer 102.

In the third step, pressure in the plasma etching apparatus is maintained as about 50 to 94 mT and the HBr gas is supplied to the plasma etching apparatus under the above-described pressure by about 80 to 240 sccm for 70 seconds. At the same time, the HeO₂ gas is supplied to the plasma etching apparatus by about 10 sccm and the He gas is supplied to the plasma etching apparatus by about 70 to 650 sccm.

At this time, the power of the source voltage supplied to the plasma etching apparatus is about 121 to 670 W, the power of the bias voltage is about 58 to 130 W, and the direct current voltage is about 45 V. The temperature at the center of the rear surface of the substrate 100 is maintained at about 4 T and the temperature at the edge of the rear surface of the substrate 100 is maintained as about 16 T.

Through the third step of the third plasma etching process, the exposed first polysilicon layer 102 is completely removed.

Then, as illustrated in FIG. 1E, an exposed gate oxide layer 101 is etched using the photoresist pattern 106 as a mask to form a tunnel oxide layer 111 in the part covered with the photoresist pattern 106.

Then, as illustrated in FIG. 1F, n-type impurities are ion implanted using the photoresist pattern 106 as a mask to form n+ type source/drain regions 600 and 700 in an active region of the substrate 100.

Then, although not shown in the drawing, the photoresist pattern 106 and the ARC 105 are removed.

In other embodiments, before the ion implantation step, the photoresist pattern 106 and the ARC 105 are first removed and then, ions may be implanted into the substrate 100 using a gate electrode formed of the tunnel oxide layer 111, the floating gate 112, the dielectric layer 113, and the control gate 114 as a mask.

According to some embodiments, the above-described method of manufacturing flash memory has the following benefit: the control gate, the dielectric layer, and the floating gate are all formed in the same etching apparatus. Therefore, it is possible to reduce the process time and to improve the reliability of the device.

While the invention has been shown and described with respect to some embodiments, it will be understood by those skilled in the art that various changes and modifications may be made without departing from the spirit and scope of the invention as defined in the following claims.

The above-described method of manufacturing the flash memory according to some embodiments, has the following effects: the Cl₂, Ar, HBr, HeO₂, He, CF₄, and CHF₃ gases are combined with each other to simultaneously form the control gate, the dielectric layer, and the floating gate in the same etching apparatus.

Therefore, it is possible to reduce the process time and to improve the reliability of the device.

What is claimed is:

1. A method of manufacturing a flash, the method comprising:
sequentially forming a gate oxide layer, a first polysilicon layer, an interlayer insulating layer, and a second polysilicon layer on a surface of a semiconductor substrate;
forming a photoresist pattern on the second polysilicon layer;
removing the exposed portion of the second polysilicon layer by using the photoresist pattern as a mask by using Cl2, HBr, HeO₂, and CF₄ gases to thereby form a control gate;
removing the exposed portion of the interlayer insulating layer by using the photoresist pattern as a mask by using Ar and CHF₃ gases to thereby form a dielectric layer; and
removing the exposed portion of the first polysilicon layer by using the photoresist pattern as a mask by using the HBr and HeO₂ gases to thereby form a floating gate.

2. The method of claim 1, wherein removing the exposed portion of the second polysilicon layer, further comprises:
supplying the Cl₂ gas by approximately 15 to approximately 95 sccm for approximately 55 seconds under a pressure of approximately 2 to approximately 10 mT;
supplying the HBr gas by approximately 80 to approximately 250 sccm for approximately 55 seconds under a pressure of approximately 2 to approximately 10 mT;
supplying the HeO₂ gas by approximately 8 to approximately 64 sccm for approximately 55 seconds under a pressure approximately 2 to approximately 10 mT; and
supplying the CF₄ gas by approximately 125 to approximately 225 sccm for approximately 55 seconds under a pressure approximately 2 to approximately 10 mT.

3. The method of claim 1, wherein removing the exposed portion of the interlayer insulating layer further comprises:
supplying the Ar gas by approximately 45 to approximately 165 sccm for approximately 50 seconds under a pressure approximately 0.9 to approximately 8 mT; and
supplying the CHF₃ gas by approximately 50 to approximately 350 sccm for approximately 50 seconds under a pressure of approximately 0.9 to approximately 8 mT.

4. The method of claim 1, wherein removing the exposed portion of the first polysilicon layer further comprises:
supplying the HBr gas by approximately 100 to approximately 250 sccm for approximately 38 seconds under a pressure of approximately 8 to approximately 21 mT; and
supplying the HeO2 gas by approximately 12 sccm for approximately 38 seconds under a pressure of approximately 8 to approximately 21 mT.

5. The method of claim 1, wherein removing the exposed portion of the second polysilicon layer further comprises using Ar and CF₄ gases.

6. The method of claim 5, wherein removing the exposed portion of the second polysilicon layer further comprises:
supplying the Ar gas by approximately 80 to approximately 200 sccm for approximately 5 seconds under a pressure approximately 2 to approximately 8 mT; and
supplying the CF₄ gas by approximately 75 to approximately 195 sccm for approximately 5 seconds under a pressure approximately 2 to approximately 8 mT.

7. The method of claim 1, wherein removing the second polysilicon layer further comprises using HBr, HeO₂, and He gases.

8. The method of claim 7, wherein removing the exposed portion of the second polysilicon layer further comprises:
supplying the HBr gas by approximately 120 to approximately 650 sccm for approximately 120 seconds under a pressure approximately 25 to approximately 125 mT;
supplying the HeO2 by approximately 8 to approximately 36 sccm for approximately 120 seconds under a pressure approximately 25 to approximately 125 mT; and
supplying the He gas by approximately 125 to approximately 225 sccm for approximately 120 seconds under a pressure approximately 25 to approximately 125 mT.

9. The method of claim 1, wherein removing the exposed portion of the first polysilicon layer further comprises using Cl₂, HBr, HeO₂, and CF₄ gases.

10. The method of claim 9, wherein removing the exposed portion of the first polysilicon layer further comprises:
supplying the Cl2 gas by approximately 20 to approximately 90 sccm for approximately 11 seconds under a pressure approximately 3.8 to 9.0 mT;
supplying the HBr gas by approximately 12 to approximately 95 sccm for approximately 11 seconds under a pressure approximately 3.8 to approximately 9.0 mT;
supplying the HeO2 gas by approximately 12 to approximately 35 sccm for approximately 11 seconds under a pressure approximately 3.8 to approximately 9.0 mT; and
supplying the CF₄ gas by approximately 80 to approximately 300 sccm for approximately 11 seconds under a pressure approximately 3.8 to approximately 9.0 mT.

11. The method of claim 1, wherein removing the exposed portion of the first polysilicon layer further comprises using HBr, HeO₂, and He gases.

12. The method of claim 11, wherein removing the exposed portion of the first polysilicon layer further comprises:
supplying the HBr gas by approximately 80 to approximately 240 sccm for approximately 70 seconds under a pressure approximately 50 to approximately 94 mT;
supplying the HeO2 gas by approximately 10 sccm for approximately 70 seconds under a pressure approximately 50 to approximately 94 mT; and
supplying the He gas by approximately 70 to approximately 650 sccm for approximately 70 seconds under a pressure approximately 50 to approximately 94 mT.

13. The method of claim 1, further comprising:
removing the photoresist pattern; and
removing the gate oxide layer using the control gate as a mask to form a tunnel oxide layer.

14. A flash memory manufactured by the flash memory manufacturing method of claim 1.
